(19) United States
(12) Patent Application Publication
(10) Pub. No.: US 2026/0214807 A1
(43) Pub. Date: Jul. 23, 2026

(54) POWER SEMICONDUCTOR MODULE AND METHOD FOR PRODUCING SAME

(71) Applicant: Schweizer Electronic AG, Schramberg (DE)

(72) Inventors: Alexander NEUMANN, Rottweil (DE); Manuel MARTINA, Rottweil (DE)

(73) Assignee: Schweizer Electronic AG, Schramberg (DE)

(21) Appl. No.: 19/444,315

(22) Filed: Jan. 9, 2026

(30) Foreign Application Priority Data
Jan. 10, 2025 (DE) 102025100755.1

(51) Int. Cl. H05K 1/185; H05K 1/02; H05K 3/46

(52) U.S. Cl. CPC H05K 1/185; H05K 1/0298; H05K 3/4608; H05K 2201/066; H05K 2201/10166; H05K 2203/107

(57) ABSTRACT

Power semiconductor module (10) for embedding in a printed circuit board assembly (100), having a base body (20) made of metal and at least one power semiconductor (32), wherein the at least one power semiconductor (32) is arranged on an associated carrier cell (30) made of metal in such a manner that a terminal, in particular a drain terminal, of the at least one power semiconductor (32) is connected to the associated carrier cell (30), and wherein the carrier cell (30) is arranged in an electrically conductive manner in an associated recess (22) of the base body (20).

### CROSS REFERENCE

This application claims priority to German Patent Application No. 102025100755.1, filed Jan. 10, 2025, the entire contents of which is hereby incorporated by reference.

### TECHNICAL FIELD

The present invention relates to a power semiconductor module for embedding in a printed circuit board assembly, and to a method for producing a power semiconductor module.

### DESCRIPTION OF THE PRIOR ART

Power semiconductor modules are used particularly in the conversion of electrical energy into different AC and DC voltage levels in high-efficiency switched-mode power supplies. Such switching power converters enable complex functions in areas such as wireless charging, mobile communications, renewable energies and intelligent motors in all sectors.

To connect multiple power semiconductors in parallel, it is known to (inter)connect them on an electrically conductive plane, i.e. on a base body made of metal. The base body populated in this way can then be incorporated into a printed circuit board assembly. Alternatively, one (or more) layers of the printed circuit board can be populated, followed by contacting the layers above and below.

### SUMMARY OF THE INVENTION

Based on this, the invention proposes a power semiconductor module comprising the features of claim 1 or 2, a method for producing a power semiconductor module comprising the features of claim 8, and a printed circuit board comprising the features of claim 12.

The invention is based on the idea of arranging a power semiconductor on a carrier cell made of metal in such a way that a terminal, in particular a drain terminal, of the power semiconductor is connected to the carrier cell. A carrier cell populated in this manner constitutes a component that can be inserted into a recess, provided for this purpose, in a base body made of metal. If multiple such carrier cells are inserted into a corresponding plurality of recesses in the base body made of metal, an arrangement of power semiconductors connected in parallel is created. This power semiconductor module can be integrated into a printed circuit board assembly.

According to the invention, a power semiconductor module for embedding in a printed circuit board assembly is thus provided, comprising a base body made of metal and a plurality of power semiconductors connected in parallel. Each of the power semiconductors is arranged on a carrier cell made of metal in such a manner that a drain terminal of the power semiconductor is connected to the associated carrier cell made of metal. In addition, each carrier cell is arranged in an electrically conductive manner in an associated recess of the base body.

The approach according to the invention opens up the possibility of producing standardized carrier cells which are populated with power semiconductors and subsequently inserted into an electrically conductive base body with corresponding recesses that match the standardized dimensions of the carrier cells.

Further advantages and embodiments of the invention emerge from the dependent claims, the description and the accompanying drawings.

It is understood that the features mentioned above and those to be explained below can be used not only in the combination specified in each case but also in other combinations or on their own without departing from the scope of the present invention.

The invention is schematically illustrated in the drawings with reference to an exemplary embodiment, and is described in detail below with reference to the drawings.

### BRIEF DESCRIPTION OF THE DRAWINGS

FIG. 1 is a highly schematic plan view of a power semiconductor module according to the invention.

FIG. 2 is a photographic illustration of a plan view of a power semiconductor module according to the invention.

FIG. 3 is a highly schematic lateral sectional view of a printed circuit board assembly having a power semiconductor module according to the invention.

FIG. 4 is a photographic illustration of a plan view of a printed circuit board with protruding connecting pieces according to FIG. 3.

FIG. 5 is a photographic illustration of a plan view of a carrier cell attached to a base body by means of laser spot welding.

FIG. 6 is, in a highly schematic lateral sectional view, an arrangement for establishing a connection by means of copper ball pressing.

FIG. 7 is a perspective view of a printed circuit board with a cut-away window showing an embedded power semiconductor module.

### DETAILED DESCRIPTION

Identical and similar features depicted in the individual figures are designated by the same reference signs.

FIG. 1 is a highly schematic plan view of a power semiconductor module 10 according to the invention.

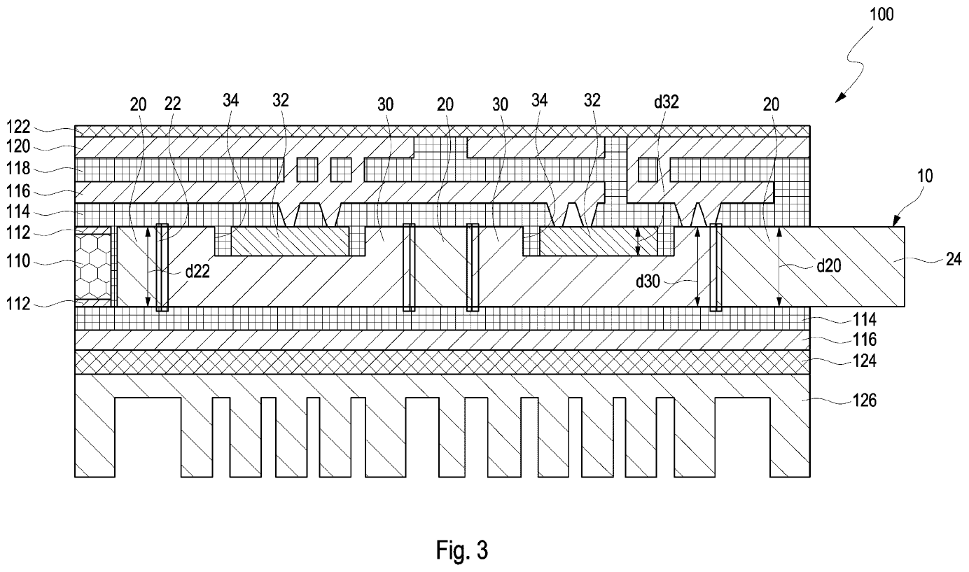

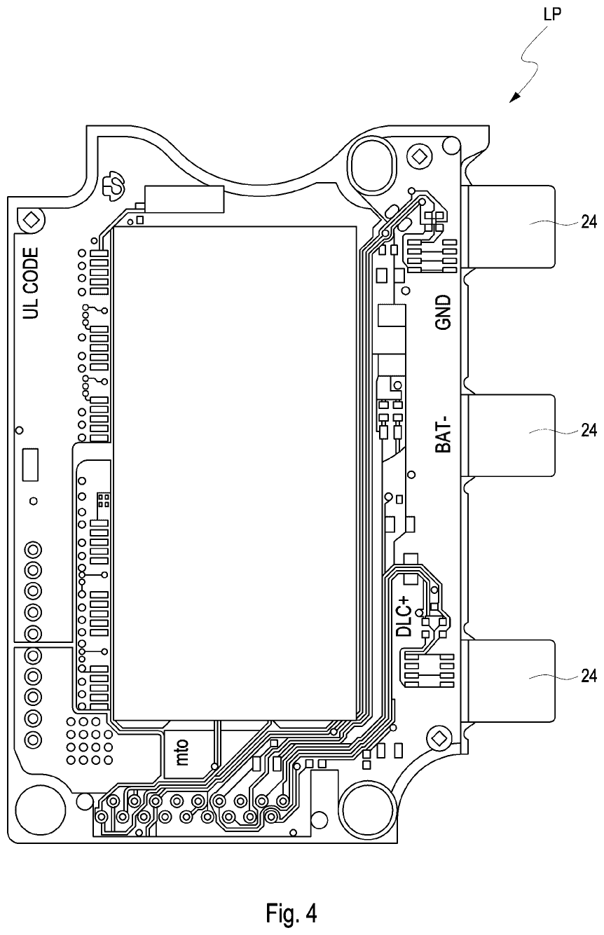

According to the invention, the power semiconductor module 10 comprises a base body 20 made of metal, in particular copper. The base body 20 is substantially rectangular, but other shapes are conceivable and can be encountered in practice. In particular, it is possible that the base body 20 has protruding pieces 24 which, in a power semiconductor module embedded in a printed circuit board assembly, protrude from the printed circuit board assembly and are used to connect to busbars/power rails (see also FIGS. 3 and 4).

The base body 20 has a plurality of recesses 22. In the illustrated exemplary embodiment, the base body 20 has a total of six recesses 22, which are arranged in two rows of three recesses each. The sketch shown is for illustrative purposes only; of course, main bodies with more or fewer recesses are possible.

The recesses 22 can have a substantially square basic shape (contour) as shown; but different contours or planform shapes are also possible.

The recesses 22 may be through-recesses, i.e. extending through the entire thickness d20 of the base body 20 (see also FIG. 3). Alternatively, it is also possible that the recesses extend only over a part of the thickness d20 of the base body 20.

The recesses 22 can be made in the metal base body 20 by milling or punching or any other suitable process.

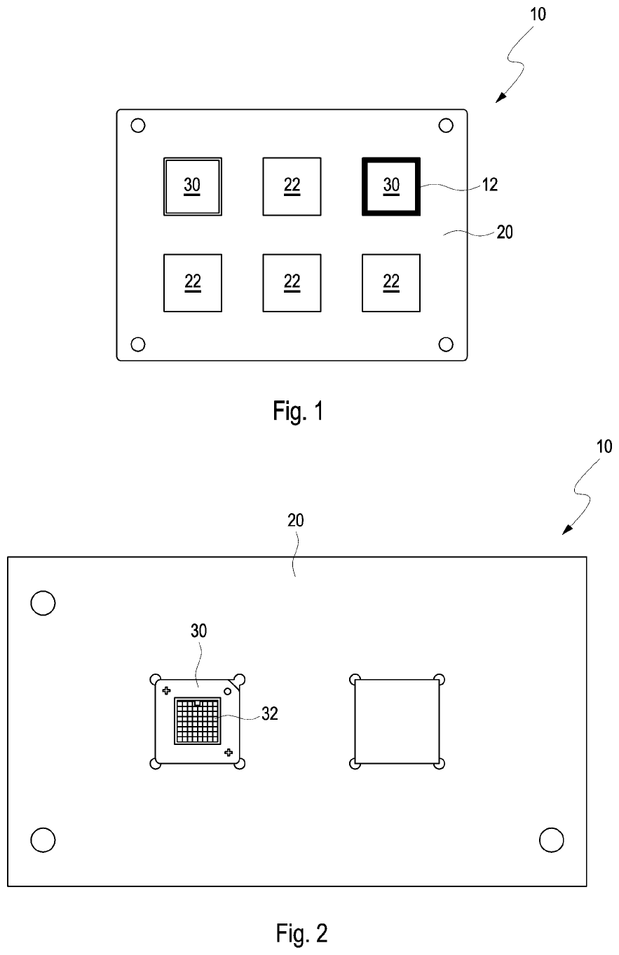

According to the invention, carrier cells 30 are inserted into the recesses 22 of the base body 20, and are each populated with a power semiconductor 32 (see also FIG. 2). According to the invention, the carrier cells are made of metal, e.g. copper. In the illustration of FIG. 1, two carrier cells 30 are inserted, namely in the top row on the far left and on the far right as seen from the viewer's perspective. Due to the highly schematic illustration, the power semiconductors 32 with which the carrier cells 30 are populated are not shown in the illustration of FIG. 1.

The individual carrier cells 30 are each populated with a power semiconductor 32, e.g. a MOSFET chip, as already described above, such that a drain terminal of the power semiconductor is connected to the metal material of the carrier cell. The source and gate terminals of the power semiconductor are located on its top surface facing away from the carrier cell.

In this way, the drain potential of an inserted carrier cell 30 is connected via the metal base body 20 to all other carrier cells inserted into the base body 20.

In order to be able to insert the carrier cells 30 into the base body 20 with a good fit and in particular with good electrical conductivity, the recesses 22 of the base body 20 are adapted to the carrier cells 30. As such, the recesses 22 of the base body 20 can be precisely designed to accommodate the carrier cells 30. This means that the recesses 22 correspond exactly to the carrier cells 30 in (planform) shape and size, so that the carrier cells 30 can be inserted precisely into the recesses 22 without significant play.

If the carrier cells 30 are, for example, square as shown and have an edge length of 11 mm each, this would mean that the corresponding recesses 22 are designed with internal dimensions of 11.2 mm±0.05 millimeters. These measurements are highly exemplary and serve only as a guide for a person skilled in the art regarding the term “precise fit”. Other geometric contours and dimensions are at the discretion of a person skilled in the art.

A thickness d30 of the carrier cell 30 preferably corresponds to a thickness d22 of the recess 22 in the base body 20. With a recess 22 passing through the base body 20, the thickness d30 of the carrier cell 30 thus corresponds to a thickness d20 of the base body 20 (see also FIG. 3). The thickness d20 of the base body 20 can be between 1 and 2 mm. Preferably the thickness of the base body is between 1.1 and 1.4 mm, more preferably between 1.2 and 1.3 mm.

The carrier cell 30 can—as can be seen from FIG. 3—have a surface recess 34 into which the power semiconductor 32 can be inserted during the population process. The depth of the recess advantageously corresponds—as shown—to a thickness d32 of the power semiconductor 32 to be used. In this case, the thickness d30 of the carrier cell 30 corresponds to the thickness d20 of the base body 20. Alternatively, the power semiconductor 32 can be placed on the carrier cell 30 without a surface recess. In this case, the sum of the thickness d30 of the carrier cell 30 and the thickness d32 of the power semiconductor 32 corresponds to the thickness d20 of the base body 20.

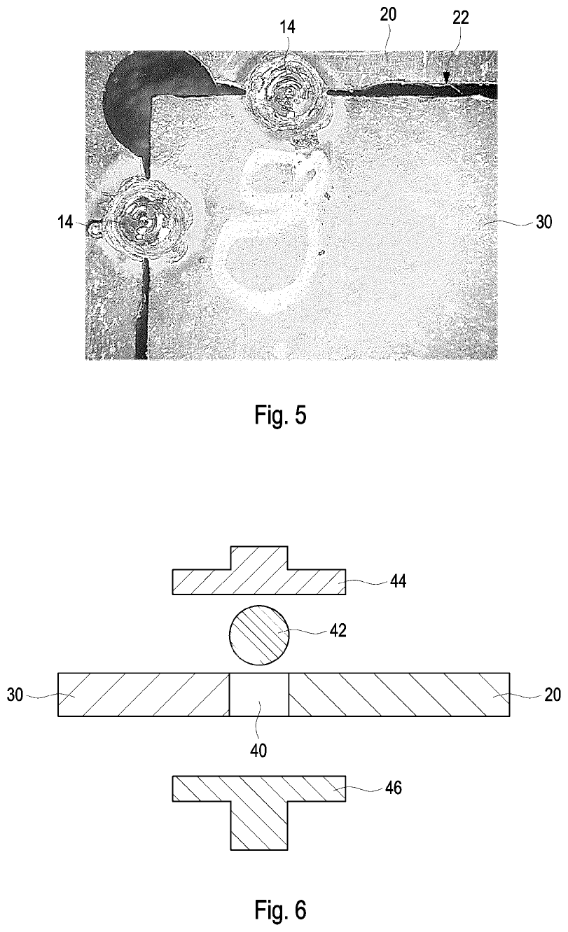

The carrier cell 30 shown in the upper left of FIG. 1 is simply inserted into the recess 22. Various methods are available to create a permanent connection between the inserted carrier cell and the base body. With particularly high accuracy of fit, i.e. only slight deviations between the outer dimensions of the carrier cell and the inner dimensions of the recess, the carrier cell can, for example, be pressed or press-fit into the recess. Furthermore, metal-joining methods such as laser welding are suitable. Laser welding can be performed around the circumference, as for the carrier cell shown in FIG. 1 at the top right (see circumferential weld seam 12). Alternatively, spot welding is also possible, e.g. in the corner regions of the carrier cell 30 (see FIG. 5, laser spot welding points 14).

Furthermore, a so-called back-punching process is also possible, in which the shape of the carrier cell is punched out of the base body 20 and, at the same time, a populated carrier cell 30 is pressed into the punched-out area. FIG. 3 is a lateral sectional view of a printed circuit board assembly 100 with an embedded power semiconductor module 10 according to the invention.

The power semiconductor module 10 is arranged in a plane with an inner layer 110 of the printed circuit board assembly 100. The inner layer 110 consists of conventional electrically insulating inner layer material, which—as shown—can be provided with a copper layer 112 on the upper and lower sides.

The printed circuit board assembly 100 is assembled in a manner known per se by inserting the power semiconductor module 10 into an area of the inner layer 110 milled out for this purpose. It is quite possible to insert multiple power semiconductor modules into a single inner layer. This allows for insulation distances of several millimeters between the individual phase conductors and from DC+.

The inner layer 110 and the power semiconductor module 10 are then covered with a first upper and lower prepreg layer 114 and copper foils 116, and subsequently laminated. Liquefied prepreg produced during lamination fills the cavities/voids, e.g. between the power semiconductor module and the inner layer, as well as in the recesses 34 of the carrier cells 30 (gaps between the power semiconductors 32 and the walls of the recesses 34). The copper foils 116 may subsequently be further built up with electroplated copper. As can be seen from the illustration, connections (vias) from the copper layers to the power semiconductors can be formed.

Further prepreg layers 118 and copper foils 120 can follow in a known manner to form further conductor planes as shown. The upper metal layer 120 can be covered with a solder resist layer 122, as also shown.

A heat sink 126 can also be attached to the bottom surface of the printed circuit board assembly 100 in a manner known per se by means of a suitable material layer 124 (e.g. solder layer or TIM (thermal interface material)).

Instead of placing the embedded components (power semiconductors) in a printed circuit board layer and contacting them with the layers above and below, as was previously done in the prior art, according to the invention a power semiconductor module is placed in an inner layer with substantially the same thickness as a printed circuit board, so that no additional inner component layer needs to be provided in the printed circuit board assembly.

The power semiconductor module 10 of FIG. 3 has, as already described above, protruding connecting pieces 24 which extend from the printed circuit board assembly 100 after it has been assembled. This is visible in the illustration of FIG. 4, which shows a photographic plan view of a printed circuit board PCB, with such connecting pieces 24, on the right-hand side of the illustration, being used for contacting/welding (not shown) busbars/current rails to the high current line. The surface of the printed circuit board PCB of FIG. 4 is partially blackened.

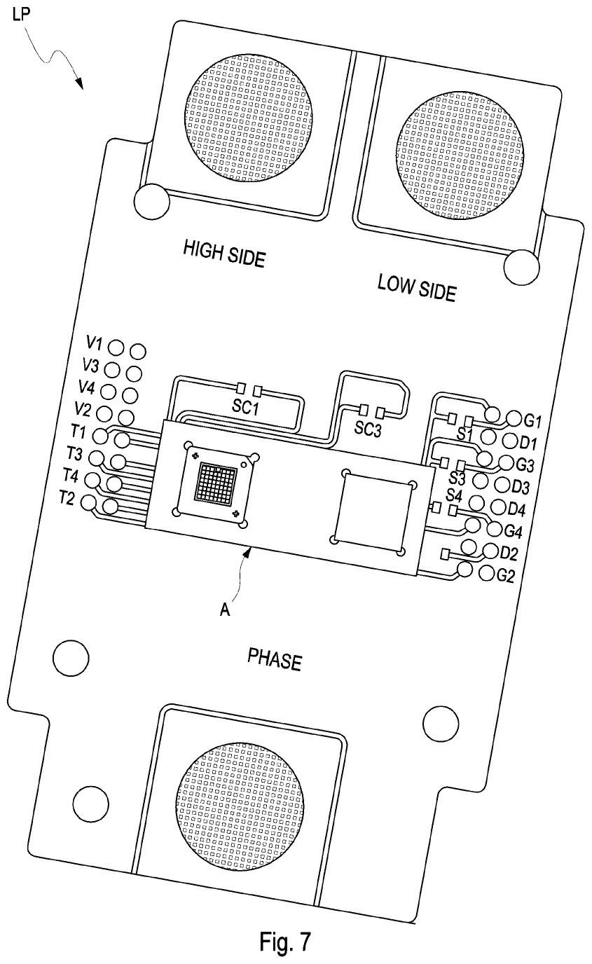

FIG. 7 also shows a printed circuit board PCB in a perspective plan view with a cut-away area that allows a view of the embedded power semiconductor module 10 of FIG. 2.

FIG. 6 shows in a highly schematic lateral sectional view an arrangement for establishing a connection by means of copper ball pressing as a further possibility to connect the carrier cell 30 to the base body 20.

In copper ball pressing, copper balls or metal balls made of a sufficiently soft material suitable for pressing are inserted or placed into boreholes which have been provided for this purpose in the area of the transition between the base body 20 and the inserted carrier cell 30, in order to then be pressed into the borehole by means of two pressing tools (or a pressing tool and a counter tool), producing a deformation. If this is carried out simultaneously at suitable opposite points along the circumference of the carrier cell, a permanent and electrically conductive connection is created between the carrier cell and the base body.

FIG. 6 schematically illustrates this procedure or approach by showing a portion of a base body 20 and a portion of a carrier cell 30 having the same thickness. In the area of the transition between the carrier cell and the base body, a (through) bore or borehole 40 is provided perpendicular to a plane of extension of the base body 20. A metal ball 42, in particular a copper ball, is placed on this borehole 40. For press-fitting the copper ball 42, plunger-like upper and lower press-in tools 44, 46 are provided. By means of a relative movement of the two press-in tools 44, 46 in the direction of the base body 20, the copper ball is pressed into the bore or borehole 40, whereby the copper ball is deformed so that, after completion of the press-in operation, it largely fills the cavity of the bore 40. The diameter of the metal ball 42 should be greater than the thickness d20 of the base body 20, i.e. the depth of the borehole 40 to be made. The diameter of the bore 40 can be chosen to be smaller, larger, or equal to the ball diameter.

With the power semiconductor module according to the invention, a better electrical connection of the drain potential of power semiconductors, especially for parallel connections, can be achieved when they are embedded in a printed circuit board assembly. Furthermore, the absence of a microvia layer results in improved thermal heat dissipation. Since the base body/bodies is/are inserted into recesses in an inner layer of a printed circuit board, higher insulation distances between the individual phase outputs can be achieved. Furthermore, an improvement in current carrying capacity and thermal heat dissipation can be observed compared to other embedding technologies, since the lateral contact between the carrier cell and the base body allows the direct connection of copper layers with thicknesses of, for example, over 400 μm, and the heat can flow away laterally with high conductivity. Finally, the use of the power semiconductor module according to the invention leads to a low-inductance design, since the semiconductor components on the carrier cells can be inserted oriented both upwards and downwards in the same workpiece. This enables new current paths for improved electrical design; in particular, lateral contact allows for shorter current paths than contact across different planes in the layer structure.

What is claimed is:

1. A power semiconductor module comprising:
a base body made of metal and at least one power semiconductor,
wherein the at least one power semiconductor is arranged on a carrier cell associated with the at least one power semiconductor, the carrier cell is made of metal in such a manner that a terminal, in particular a drain terminal, of the at least one power semiconductor is connected to the carrier cell, and
wherein the carrier cell is arranged in a recess of the base body in an electrically conductive manner.

2. A power semiconductor module comprising:
a base body made of metal and a plurality of power semiconductors connected in parallel,
wherein each one of the plurality of power semiconductors is arranged on a carrier cell made of metal in such a manner that a terminal, in particular a drain terminal, of each one of the plurality of power semiconductors is connected to the carrier cell, and
wherein each carrier cell is arranged in a recess of the base body in an electrically conductive manner.

3. The power semiconductor module of claim 2, wherein each recess of the base body is configured in a form-fitting manner for accommodating the carrier cell.

4. The power semiconductor module of claim 2, wherein each of the one of the plurality of power semiconductors include a thickness of each carrier cell corresponds to a thickness of the recess of the base body, wherein a contour of the carrier cell corresponds to a contour of the recess of the base body.

5. The power semiconductor module of claim 2, wherein each of the one of the plurality of power semiconductors are arranged flush in a surface recess of the carrier cell.

6. The power semiconductor module of claim 2, wherein each one of the plurality of power semiconductors include the carrier cell inserted into the recesses of the base body by one of the group including laser welding, pressing, and press-fitting.

7. The power semiconductor module of claim 2, wherein each of the one of the plurality of power semiconductors include the recess of the base body is produced by one of the group including milling and punching.

8. A method for producing a power semiconductor module, comprising the following steps:
populating at least one carrier cell made of metal with a power semiconductor in such a manner that a terminal, in particular a drain terminal, of the power semiconductor is connected to the carrier cell ;
providing a base body made of metal and having at least one recess, and
inserting the at least one populated carrier cell into an associated recess.

9. The method of claim 8, wherein a surface recess is formed in the carrier cell prior to the populating step, into which surface recess the power semiconductor is inserted.

10. The method of claim 8, wherein the at least one carrier cell is inserted into the associated recess of the base body by one of the following including laser welding, pressing, and press-fitting.

11. The method of claim 8, wherein for connecting an inserted populated carrier cell to the base body, a metal ball press-fitting is performed comprising the following steps:
introducing at least one bore in a transition region between the carrier cell and the base body;
placing a metal ball on, or inserting a metal ball into each of the at least one bore, and
press-fitting the metal ball into the bore by means of press-in tools while deforming the metal ball.

12. The power semiconductor module of claim 2, further comprising a printed circuit board assembly, wherein the power semiconductor module is embedded in a printed circuit board assembly.

13. The power semiconductor module of claim 1, wherein the recess of the base body is configured in a form-fitting manner for accommodating the carrier cell.

14. The power semiconductor module of claim 1, wherein the at least one power semiconductor includes a thickness of the carrier cell corresponds to a thickness of the recess of the base body, wherein a contour of the carrier cell corresponds to a contour of the recess of the base body.

15. The power semiconductor module of claim 1, wherein each at least one power semiconductor is arranged flush in a surface recess of the carrier cell.

16. The power semiconductor module of claim 1, wherein the carrier cell is inserted into the recesses of the base body by one of the group including laser welding, pressing, and press-fitting.

17. The power semiconductor module of claim 1, wherein the at least one power semiconductor includes the recess of the base body is produced by one of the group including milling and punching.

18. The power semiconductor module of claim 1, further comprising a printed circuit board assembly, wherein the power semiconductor module is embedded in a printed circuit board assembly.
